(19) United States
(12) Patent Application Publication
(10) Pub. No.: US 2022/0310813 A1
(43) Pub. Date: Sep. 29, 2022

(54) FORMING SHIELD CONTACTS IN A SHIELDED-GATE TRENCH POWER MOSFET

(71) Applicant: SEMICONDUCTOR COMPONENTS INDUSTRIES, LLC, Phoenix, AZ (US)

(72) Inventors: Zia HOSSAIN, Tempe, AZ (US); Balaji PADMANABHAN, Chandler, AZ (US); Sauvik CHOWDHURY, San Jose, CA (US)

(73) Assignee: SEMICONDUCTOR COMPONENTS INDUSTRIES, LLC, Phoenix, AZ (US)

(21) Appl. No.: 17/653,235

(22) Filed: Mar. 2, 2022

Related U.S. Application Data
(60) Provisional application No. 63/166,919, filed on Mar. 26, 2021.

(51) Int. Cl. H01L 29/423; H01L 29/66; H01L 29/78; H01L 29/40

(52) U.S. Cl. CPC H01L 29/4236; H01L 29/66734; H01L 29/7813; H01L 29/407

(57) ABSTRACT

A device includes a mesa disposed between a pair of vertical trenches in a semiconductor substrate. A gate electrode is disposed in each of the pair of vertical trenches, and a shield electrode is disposed below each of the gate electrodes in the pair of vertical trenches. The device further includes a bridge connection trench traversing the mesa. The bridge connection trench is in fluid communication with each of the pair of vertical trenches. A bridge shield electrode is disposed in the bridge connection trench and is coupled to the shield electrode disposed below each of the gate electrodes in the pair of vertical trenches.

### CROSS-REFERENCE TO RELATED APPLICATION

This application claims priority to, and the benefit of, U.S. Provisional Patent Application No. 63/166,919, filed on Mar. 26, 2021, which is incorporated by reference in its entirety herein.

### TECHNICAL FIELD

This description relates to contacts in a shielded gate trench MOSFET.

### BACKGROUND

As semiconductor device (e.g., device cell dimensions) shrink, it is increasingly difficult to make gate and shield contacts in a semiconductor device (e.g., a shielded gate trench MOSFET). Different lithography design rules may be used for active areas and contact areas of the semiconductor device. For proper device functioning, charge in the drift regions of the MOSFET has to be well controlled and balanced in both the active areas and the contact areas to avoid adversely affecting the breakdown voltage of the device.

### SUMMARY

In a general aspect, a device (e.g., a MOSFET) includes a mesa disposed between a pair of vertical trenches in a semiconductor substrate. The pair of vertical trenches includes a first vertical trench aligned parallel to a second vertical trench from the pair of vertical trenches. A gate electrode is disposed in each of the pair of vertical trenches and a shield electrode disposed below each of the gate electrodes in the pair of vertical trenches. Further, a bridge connection trench traverses the mesa and joins the pair of vertical trenches. The bridge connection trench is aligned along a direction perpendicular to the parallel direction of the pair of vertical trenches. A bridge shield electrode disposed in the bridge connection trench and coupled to each of the shield electrodes in the pair of vertical trenches. The bridge shield electrode exposes a shield electrode contact element in the bridge connection trench. The shield electrode contact element in the bridge connection trench is connected to a source metal of the device.

In a general aspect, a device (e.g., a MOSFET) includes a first mesa disposed between a first pair of vertical trenches in a semiconductor substrate, and a second mesa disposed between a second pair of vertical trenches in the semiconductor substrate. The first mesa, the second mesa, and the first and second pairs of vertical trenches extend longitudinally from an active region of the device through a shield contact area of the device on the semiconductor substrate. Further, a gate electrode is disposed in each of the first and second pairs of vertical trenches and a shield electrode is disposed underneath the gate electrode in each of the first and second pairs of vertical trenches. A first bridge connection trench is disposed across the first mesa at a first location, and a second bridge connection trench is disposed across the second mesa at a second location. The first bridge connection trench is in fluid communication with the first pair of vertical trenches, and the second bridge connection trench is in fluid communication with the second pair of vertical trenches.

In a general aspect, a method includes forming a mesa between a pair of vertical trenches in a semiconductor substrate and forming a bridge connection trench within the mesa in fluid communication with the pair of vertical trenches. The method further includes disposing a shield electrode in each of the pair of vertical trenches along a length of the pair of vertical trenches, disposing a gate electrode aligned longitudinally above the shield electrode in the pair of vertical trenches, and disposing a bridge shield electrode in the bridge connection trench. The bridge shield electrode is coupled to the shield electrode disposed below the gate electrode in the pair of vertical trenches. The method further includes exposing a shield electrode contact element in the bridge connection trench.

### BRIEF DESCRIPTION OF THE DRAWINGS

FIG. 1A illustrates a portion of an example device layout of a shielded gate trench MOSFET device.

FIG. 1B is a cross-sectional view of a portion of the shielded gate trench MOSFET device of FIG. 1A.

FIG. 1C is a cross-sectional view of a portion of the shielded gate trench MOSFET device of FIG. 1A.

FIG. 1D illustrates another portion of an example device layout of the shielded gate trench MOSFET device of FIG. 1A.

FIG. 2A illustrates a portion of an example device layout of a shielded gate trench MOSFET device.

FIG. 2B illustrates a cross-sectional view of a portion of the shielded gate trench MOSFET device of FIG. 2A.

FIG. 2C illustrates another portion of an example device layout of the shielded gate trench MOSFET device of FIG. 2A.

FIG. 3 illustrates an example device layout of a shielded gate trench MOSFET device with bridge connection trenches.

FIG. 4 illustrate portions of an example device layout of a shielded gate trench MOSFET device with bubble mesas.

FIG. 5 illustrates a portion of a device layout having a mesa pattern including bubble mesas and non-bubble mesas.

FIG. 6 illustrates use of an example repeated pattern of bubble and non-bubble mesas in a device layout.

FIG. 7A is an illustration of a cross-sectional view of a shielded gate trench MOSFET device.

FIG. 7B is a top view of an example contact structure layout of the shielded gate trench MOSFET device of FIG. 7A.

FIG. 8 illustrates an example device layout of a shielded gate trench MOSFET device including both narrow trenches and wide trenches.

FIG. 9 illustrates an example method for making contacts to shield electrodes in a shielded gate trench MOSFET device.

### DESCRIPTION

Metal oxide semiconductor field effect transistor (MOSFET) devices are used in many power switching applications. In a typical MOSFET device, a gate electrode provides turn-on and turn-off control of the device in response to an applied gate voltage. For example, in an N-type enhancement mode MOSFET, turn-on occurs when a conductive N-type inversion layer (i.e., channel region) is formed in a p-type body region in response to a positive gate voltage, which exceeds an inherent threshold voltage. The inversion layer connects N-type source regions to N-type drain regions and allows for majority carrier conduction between these regions.

In a trench MOSFET device, a gate electrode is formed in a trench that extends downward (e.g., vertically downward) from a major surface of a semiconductor material (also can be referred to as a semiconductor region) such as silicon. Further, a shield electrode may be formed below the gate electrode in the trench (and insulated via an inter-electrode dielectric). Current flow in a trench MOSFET device is primarily vertical (e.g., in an N doped drift region) and, as a result, device cells can be more densely packed. A device cell may, for example, include a trench that contains the gate electrode and the shield electrode. An adjoining mesa that contains the drain, source, body, and channel regions of the device.

A current handling capability of a trench MOSFET device is determined by its gate channel width. To minimize cost it may be important to keep the transistor's die area size as small as possible and increase the width of the channel surface area (i.e., increase the “channel density”) by creating cellular structures repeated over the whole area of a MOSFET die. A way to increase the channel density (and therefore increase channel width) is to reduce the size of the device cell and pack more device cells at a smaller pitch in a given surface area.

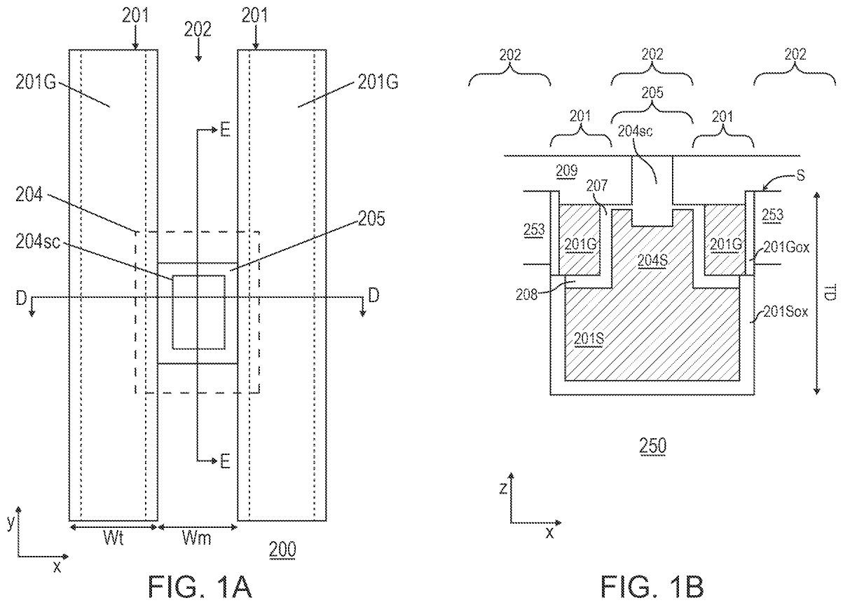

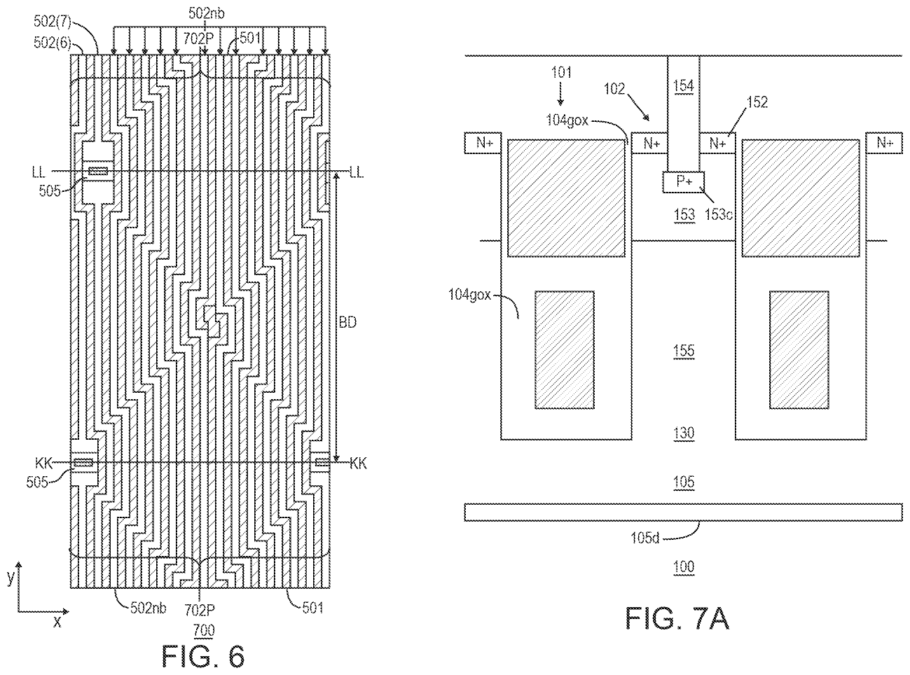

An example trench MOSFET device may include an array of hundreds or thousands of device cells (each including a trench and an adjoining mesa). A device cell may be referred to herein as a trench-mesa cell because each device cell geometrically includes a trench and a mesa (or two half mesas) structures. Shield and gate electrodes (e.g., shield electrode 104s and gate electrode 104g, FIG. 7A) may be formed inside of a linear trench (e.g., trench 101) running along (e.g., aligned along) a mesa (e.g., mesa 102). The shield and gate electrodes may be made of polysilicon (e.g., “n+ shield poly silicon” and “n+ gate poly silicon”) and isolated from each other by a dielectric layer (e.g., an inter-poly dielectric (IPD) layer 208, FIG. 1B). The IPD layer may, for example, be an oxide layer. The shield and gate electrodes are also isolated from silicon in the mesa by dielectric layers (e.g., shield dielectric and gate dielectric layers).

To ensure proper electrical contact of every cell, a “planar stripe” structure is often used for trench MOSFETS fabricated on a semiconductor die surface. In the planar stripe structure, a gate electrode (“gate”) and a shield electrode (“shield poly”) within a trench (e.g., a linear trench) are disposed to run along (e.g., aligned along) a length of the trench in a longitudinal stripe. The gate electrode (e.g., made with gate poly) is disposed along the length of the trench on top of (or above) the shield electrode (e.g., made with shield poly). The gate poly in the trench is exposed and contacted at a stripe end by a gate runner (e.g., gate metal) and the shield electrode (shield poly) in the trench is exposed and brought up to the surface (using a masking step) at an location along the length of the trench for contact by a source metal.

In modern trench MOSFET devices (e.g., with narrow line widths) shield resistance is a factor affecting device efficiency and performance. Lower shield resistance can be obtained by making multiple contacts to the shield poly in a trench (e.g., by bringing the shield poly vertically up to the surface at multiple locations to make multiple shield contacts with source metal).

Bringing the shield poly up vertically to the surface (from directly below the gate poly) interrupts or breaks the continuity of the gate poly running along the length of the trench. The gate poly is broken into two discontinuous segments by each instance of the shield poly brought up vertically to the surface. In example implementations, two separate gate runners (e.g., gate metal strips) at ends of the stripe may contact the two discontinued gate poly segments created by a single instance of the shield poly being brought vertically up through the trench to the surface. Multiple instances of the shield poly being brought vertically up through the trench to the surface can result in in isolated gate poly segments that are floating (i.e., not connected by the two separate gate runners).

The disclosure herein describes example device configurations or layouts for making multiple contacts at different locations to a shield electrode in a trench while preserving continuity of the gate electrode running above the shield electrode in the trench.

In example implementations of device configurations or layouts for making multiple contacts at different locations to the shield electrode, a mesa is disposed between a pair of vertical trenches (e.g., a first vertical trench aligned parallel to a second vertical trench). A bridge connection trench is disposed across (e.g., through) the mesa between two adjacent trenches. The bridge connection trench joins or links the two adjacent trenches. Disposing the bridge connection trench may involve cutting or etching the mesa and opening a link or passageway joining or connecting the two adjacent trenches (such that the bridge connection trench is in fluid communication with the two adjacent trenches). The adjacent trenches can be adjoining trenches via the bridge connection trench. In some implementations, the shield electrodes in the adjacent trenches are brought to the surface of the device through or from the bridge connection trench. The shield electrodes in the adjacent trenches are brought up to about the top surface of the bridge connection trench without breaking continuity of the gate electrode that runs above the shield electrode in the adjacent trenches. A shield electrode contact element (bridge shield electrode contact element) may be disposed above the bridge connection trench (i.e., the surface of the trench filled, e.g., with oxide or a shield poly for a bridge shield electrode) across the mesa between adjacent trenches.

FIG. 1A shows a portion of an example device layout 200 of a shielded gate trench MOSFET device (e.g., device 250, FIGS. 1B and 1C) in which a bridge connection trench is disposed across a mesa to join or link trenches adjoining the mesa.

FIG. 1A shows, for example, two trenches 201 of the device running parallel (e.g., substantially parallel) to each other, and a mesa 202 between the two trenches 201. Trenches 201 and mesa 202 may be linear trenches and a linear mesa (running, for example, in the y direction), respectively. Trenches 201 and mesa 202 may have uniform widths Wt and Wm (e.g., horizontal widths in the x direction), respectively. A bridge connection trench (e.g., bridge connection trench 205) may traverse (i.e., cut across) in mesa 202 at a location and inter-connect or join the two trenches 201 adjoining mesa 202. Bridge connection trench 205 may be perpendicular (e.g., substantially perpendicular) to the lengths of trenches 201 and mesa 202 (i.e., bridge connection trench 205 may traverse (cut across) mesa 202 in the x direction). Bridge connection trench 205 may be in fluid communication with each of the two trenches 201. The trenches (i.e. trenches 201 and bridge connection trench 205) may have a same or about a same vertical depth TD referenced, for example, from a top surface of mesa 202 (see e.g., FIGS. 1B and 1C).

Gate electrodes (e.g., gate electrodes 201G) of the device may run through (be disposed within) the two trenches 201. Further, shield electrodes of the device may run below (e.g., be disposed below) or underneath the gate electrodes in the trenches. The shield electrodes are not visible in FIG. 1A because they are below or underneath the gate electrodes. The shield electrode may be made of polysilicon material (shield poly). As shown in FIG. 1B, the shield poly material of the shield electrodes (e.g., shield electrode 201S) can be extended from trenches 201 sideways (in a x direction, perpendicular to the longitudinal direction of trenches) into bridge connection trench 205. In FIG. 1A, a region of device layout 200 over which the shield poly material is extended into the bridge connection trench 205 is schematically shown by a dashed rectangle 204. The shield poly material extended into the bridge connection trench 205 may be brought up in height to about the surface of bridge connection trench 205 (over at least a portion of a width of bridge connection trench 205). The shield poly material extended into the bridge connection trench 205 may be referred to herein as the bridge shield electrode.

The shield poly in bridge connection trench 205 can be exposed as a shield electrode contact element (e.g., bridge shield electrode contact element 204sc) for connection with, for example, source metal of the device.

FIG. 1B shows a cross-sectional view of a portion of a device 250 that may be formed with device layout 200. The cross-sectional view (taken along line D-D in FIG. 1A in the z-x plane) is across, for example, trenches 201, and a bridge connection trench 205 disposed across a mesa 202 between the two trenches 201. The trenches (i.e. trenches 201 and bridge connection trench 205) may have about a same depth TD (referenced, e.g., from a top surface of mesa 202).

As shown in FIG. 1B, the two trenches 201 include gate electrodes 201G (e.g., made of gate poly), and shield electrodes 201S (e.g., made of shield poly) that are disposed below or underneath gate electrodes 201G in the two trenches 201. An IPD layer 208 may isolate gate electrodes 201G from shield electrodes 201S that are disposed below or underneath gate electrodes 201G in the two trenches 201. A gate oxide (e.g., gate oxide 201Gox) may be disposed between the gate electrodes and p-body regions (p-body 253) of adjoining mesas 202. Shield electrodes 201S in the trenches may be isolated from adjoining mesas 202 by a dielectric layer (e.g., shield oxide 201Sox).

The shield poly of shield electrodes 201S may extend sideways into bridge connection trench 205 and rise up as bridge shield electrode 204S along sides of gate electrodes in bridge connection trench 205 up to about a top surface S of mesa 202. In example implementations, IPD layer 208 isolating gate electrodes 201G from shield electrode 201S may be a boron silica glass (BSG) layer. Further, bridge shield electrode 204S (in bridge connection trench 205) may be isolated from the gate poly (in trenches 201) by a dielectric layer 207 (e.g., an oxide layer such as a boron silica glass (BSG)). Dielectric layer 207 and IPD layer 208 may be formed in a single processing step or in separate processing steps. The gate electrodes 201G in the two trenches 201 remain separated in distance and are not in electrical contact with each other (being isolated by dielectric layer 207 (e.g., a boron silica glass (BSG)) from the bridge shield electrode 204S in the bridge connection trench 205). An inter-layer dielectric (e.g., inter-layer dielectric (ILD) 209) may be disposed on top of the device, for example, to passivate exposed surfaces (e.g., surface S of mesa 202 or surface SS of shield poly).

A shield electrode contact element (e.g., bridge shield electrode contact element 204sc) is formed on a surface SS of shield poly (e.g., in some example implementations by patterning, and etching through, inter-layer dielectric 209).

FIG. 1C shows another cross-sectional view of a portion of a device 250 that may be formed with device layout 200. The cross-sectional view (taken along line E-E in FIG. 1A in the z-y plane) is across, for example, a length (in the y direction) of bridge connection trench 205 disposed across mesa 202. Bridge connection trench 205 includes bridge shield electrode 204S. In the example implementation shown, shield poly material of bridge shield electrode 204S may have a top surface SS at about a same height as top surface S of mesa 202 and covered with inter-layer dielectric 209.

As noted previously, bridge shield electrode contact element 204sc is formed on surface SS of the shield poly (e.g., in some implementations by patterning, and etching through, inter-layer dielectric 209).

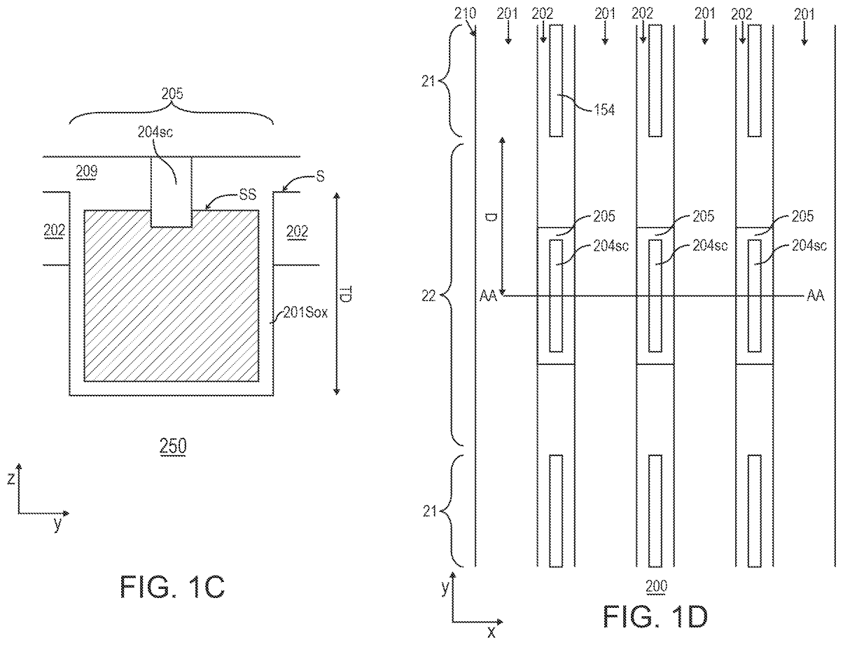

FIG. 1D shows of a larger portion of example device layout 200 (shown in FIG. 2A) of the trench MOSFET device (e.g., device 250, FIGS. 1B and 1C).

As shown in FIG. 1D, device layout 200 includes a plurality of mesas 202 and trenches 201 of the trench MOSFET device formed, for example, on a silicon substrate 210. Mesas 202 and trenches 201 are shown, for example, as generally running longitudinally (in the y direction) across silicon substrate 210 between source areas 21. Source and body contact elements 154 of the device are formed in the mesas 202 in source areas (e.g., source area 21) of the device. In FIG. 2C, the source areas 21 are shown, for example, at the top and lower portions of layout 200.

Further, bridge connection trenches 205 linking or joining trenches 201 are formed across mesas 202 in a bridge connection area 22. A bridge connection trench 205 may join or connect the pair of trenches (i.e. the two trenches 201) that are adjacent to a mesa 202.

Bridge connection trenches 205 may be formed, for example, along a horizontal axis (e.g., axis AA-AA), across some or all mesas 202 in device layout 200. Bridge connection trenches 205 across different mesas 202 in device layout 200 may be located at a uniform distance (e.g., distance D) from source area 21 along the lengths of the mesas.

Bridge connection trenches 205 may include shield poly (e.g., bridge shield electrode 204S) rising up to (brought up to) about a top surface of bridge connection trenches 205. A bridge shield electrode 204S may be exposed in a bridge connection trench 205 as a shield electrode contact element (e.g., bridge shield electrode contact element 204sc) for contacting with, for example, a source metal of the device.

In some implementations, a bridge shield electrode 204S (e.g., shield poly) may not be brought up or rise up to about top surface S of the mesa adjacent to the bridge connection trench. The shield poly of bridge shield electrode 204S may rise up only part of the way (e.g., up to about a same height of shield electrode 201S in a trench 201) toward the top surface of the bridge connection trench (in other words, bridge shield electrode 204S may only partially fill bridge connection trench 205). A dielectric layer (e.g., a full fill oxide) disposed over bridge shield electrode 204S may fill a volume of the bridge connection trench. A shield electrode contact element (bridge shield electrode contact element) may be formed on a surface of the bridge shield electrode 204S in the bridge connection trench by etching through the full fill oxide.

FIGS. 2A and 2C shows portions of an example device layout 300 of a trench MOSFET device (e.g., device 350, FIG. 2B) in which bridge shield electrodes 204S disposed in bridge connection trenches are covered by dielectric layer (e.g., a full fill oxide).

FIG. 2A shows, for example, two adjacent trenches 301 of the device running parallel (e.g., substantially parallel) to each other along a mesa 302. Mesa 302 may be a linear mesa (running, for example, generally in the y direction) and having a uniform (e.g., substantially uniform) width Wm (e.g., in the x direction). Trenches 301 (like trenches 201, FIG. 1A) may be linear trenches (running, for example, generally in the y direction). A bridge connection trench (e.g., bridge connection trench 305) is disposed across mesa 302 to inter-connect or join the two adjacent trenches 301. Bridge connection trench 305 may be in fluid communication with each of the two trenches 301. The trenches (i.e. trenches 301 and bridge connection trench 305) may have about a same depth TD (referenced, e.g., from a top surface of mesa 302) (FIG. 2B)).

Gate electrodes (e.g., gate electrodes 301G, FIG. 2B) of the device run through (e.g., disposed within) the two adjacent trenches 301. Further, shield electrodes of the device run below (e.g., disposed below) the gate electrodes in trenches 301. The shield electrodes in trenches 301 are not visible in FIG. 2A because they are hidden below or underneath the gate electrodes.

The shield electrodes (shield poly) in trenches 301 may extend into bridge connection trench 305 as bridge shield electrode 304S. A region of device layout 200 over which the shield poly material is extended into the bridge connection trench 305 is schematically shown by a dashed rectangle 304. The shield poly (bridge shield electrode 304S) in bridge connection trench 305 may have a height (z direction) that is only part of the way up toward a top surface of the bridge connection trench. Bridge shield electrode 304S in bridge connection trench 305 may be covered with a dielectric layer (e.g., a full fill oxide 306, FIG. 2B) to fill bridge connection trench 305 up to about a same height as the height of a top surface S of mesa 302 (or bridge connection trench 305). The full fill oxide may, for example, be a gap-filing oxide such as BSG or a fluorine-doped plasma-enhanced chemical vapor deposition (PECVD) tetraethylorthosilicate (TEOS) silicon dioxide material.

Bridge shield electrode 304S covered by full fill oxide 306 may be exposed in bridge connection trench 305 as a shield electrode contact element (e.g., bridge shield electrode contact element 304sc) by etching (e.g., deep etching) a hole through full fill oxide 306. Bridge shield electrode contact element 304sc may be configured for contacting a source metal (not shown) of the device.

FIG. 2B shows a cross-sectional view of a portion of a device 350 that may be formed with device layout 300. The cross-sectional view (in the x-z plane, taken along line E-E in FIG. 2A) is across, for example, two trenches 301, and a bridge connection trench 305 disposed across a mesa 302 between the two trenches 301. The trenches (i.e. trenches 301 and bridge connection trench 305) may have about a same vertical depth TD (referenced, e.g., from a top surface of mesa 302 or bridge connection trench 305).

As shown in FIG. 2B, the two trenches 301 include gate electrodes 301G (e.g., made of gate poly) and shield electrodes 301S (e.g., made of shield poly) that are disposed below or underneath gate electrodes 301G. A gate oxide (e.g., gate oxide 301Gox may be disposed between the gate electrodes and p-body regions (p-body 353) of adjoining mesas 302.

The shield poly of shield electrodes 301S in trenches 301 may extend into bridge connection trench 305 to form a bridge shield electrode 304S. The shield poly in bridge connection trench 305 may have a height SH (z direction) that is only part of the way up toward a top surface S of the bridge connection trench. Bridge shield electrode 304S in bridge connection trench 305 may be covered with a dielectric layer (e.g., full fill oxide 306) to about a same height as the height of top surface S of bridge connection trench 305. The full fill oxide may, for example, be a gap-filing oxide such as BSG or a fluorine-doped plasma-enhanced chemical vapor deposition (PECVD) tetraethylorthosilicate (TEOS) silicon dioxide material.

The shield electrodes (shield electrodes 301S) in the trenches may be isolated from adjoining mesas 302 by a dielectric layer (e.g., shield oxide 301Sox). Further, the shield poly in shield electrodes 301S may be isolated from the gate poly (gate electrodes 301G) by a dielectric layer 308 (e.g., an oxide layer, a BSG layer). An inter-layer dielectric (e.g., inter-layer dielectric (ILD) 309) may be disposed on top of the device, for example, to passivate or protect exposed surfaces (e.g., surface S of mesa 302, surface of full fill oxide 306, etc.).

Bridge shield electrode 304S may be exposed on surface S of bridge connection trench 305 as a shield electrode contact element (e.g., bridge shield electrode contact element 304sc), for example, by patterning, and etching through ILD 309 and full fill oxide 306).

The shield poly covered by full fill oxide 306 may be exposed in bridge connection trench 305 as a shield electrode contact element (e.g., bridge shield electrode contact element 304sc) by etching (e.g., deep etching) a hole (e.g., hole 306H) through the full fill oxide 306. Bridge shield electrode contact element 304sc may be configured for connecting with, for example, a source metal of the device.

FIG. 2C shows of a larger portion of example device layout 300 (shown in FIG. 2A) of the trench MOSFET device (e.g., device 350, FIG. 2B) in which bridge connection trenches are disposed across the mesas to interconnect adjacent trenches of the trench MOSFET device.

As shown in FIG. 2C, device layout 300 includes a plurality of mesas 302 and trenches 301 of the trench MOSFET device formed, for example, on a semiconductor substrate 310. Mesas 302 and trenches 301 are shown, for example, as generally running across silicon substrate 310 longitudinally in the y direction between source areas 31. Source and body contact elements 154 of the device are formed in mesas 302 in source areas (e.g., source area 31) of the device. In FIG. 2C, the source areas 31 are shown, for example, at the top and lower portions of layout 300.

Further, bridge connection trenches 305 are formed across mesas 302 to link adjacent trenches 301 in a bridge connection area 32 between source areas 31. A bridge connection trench 305 may join or connect adjacent trenches 301 on either side of a mesa 302. In an example implementation, bridge connection trenches 305 may be formed along a horizontal axis (e.g., axis AA-AA) across some or all mesas 302 in device layout 300. The bridge connection trenches 305 on different mesas 302 in device layout 300 may be disposed at a uniform distance (e.g., distance D) from a source area 31 along the lengths of the mesas.

In some example implementations, with reference to FIG. 1D, bridge connection trenches 205 on different mesas 202 in device layout 200 may be disposed at different distances from the source areas (e.g., source area 21) along the lengths of the mesas. Similarly, with reference to FIG. 2C, bridge connection trenches 305 on different mesas 302 in device layout 300 may be disposed at different distances from the source areas (e.g., source area 31) along the lengths of the mesas. In other words, the distances at which the bridge connection trenches (e.g., bridge connection trenches 205 or bridge connection trenches 305) are disposed across different mesas in a device layout may be staggered.

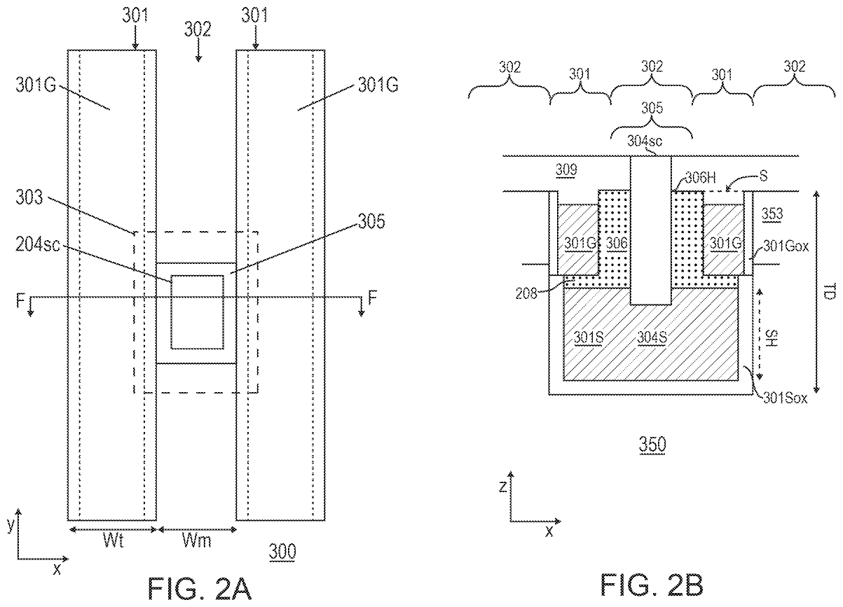

FIG. 3 shows an example device layout 400 of a shielded gate trench MOSFET device with bridge connection trenches staggered across mesas 402.

As shown in FIG. 3, bridge connection trenches 405 may be formed across different mesas 402 to connect adjacent trenches 401 in a bridge connection area 42 of the device. Bridge connection trenches 405 across some mesas 402 may be formed about a horizontal axis (e.g., axis AA-AA, parallel to the x direction) Bridge connection trenches 405 across other mesas 402 may be formed about a horizontal axis (e.g., axis BB-BB, parallel to the x direction), for example, at about a distance D1 from axis AA-AA. Thus, bridge connection trenches 405 may be disposed in a staggered configuration (e.g., at about distance D1 along the y axis from each other). In the example shown in FIG. 3, bridge connection trenches 405 are disposed in a staggered configuration on alternating mesas 402 (in the x direction) at alternating (staggered) distances zero and D1 from axis AA-AA along the longitudinal lengths of the mesas.

In the example device layouts (e.g., layout 200, 300 and 400) discussed above with reference to FIGS. 1A through 3, the mesas (e.g., mesas 202, 302, and 402) and the trenches (e.g., trenches 201, 301, and 402) adjoining the mesas are generally linear structures with uniform (e.g., substantially uniform) widths (e.g., mesa width Wm, FIG. 2A) along their lengths. Disposing a bridge connection trench (e.g., bridge connection trench 205, 305 or 405) across a mesa may involve etching or cutting the mesa to form a passageway or opening linking the two adjoining trenches. A width of a bridge connection trench (in the x direction) between the two adjoining trenches is determined by the width of the mesa (in the x direction) (e.g., mesa width Wm, FIG. 2A).

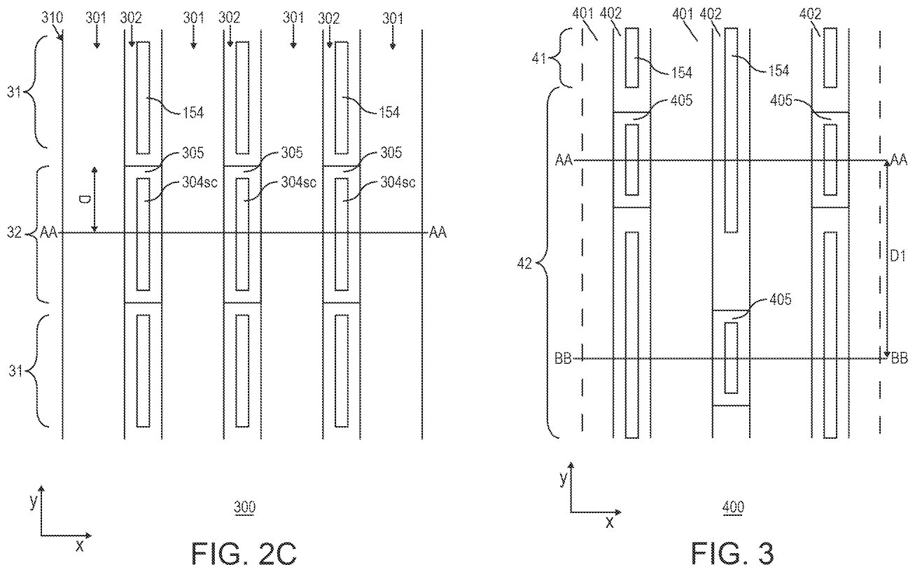

In example implementations, portions of an otherwise uniform-width mesa can be widened at locations where bridge connection trenches are to be placed across the mesa for linking or joining adjoining trenches. A widened mesa portion may have a width (e.g., horizontal width Wmb, FIG. 4)) (in the x direction) which is greater than the width (e.g., width Wm) of the non-widened mesa portions. The width of bridge connection made across a widened portion of the mesa may correspond to the width Wmb of the widened portion. An end of a mesa at a bridge connection trench made in the widened portion may be wider than an end of the mesa at a bridge connection trench if made in a non-widened portion. The widened portion of a mesa may be referred to as a bubble; a mesa with a widened portion may be referred to as a bubble mesa; and the end of the mesa at a bridge connection trench in the widened portion may be referred to as a bubble mesa end. The adjoining trenches may be rerouted to conform to the shape of the widened portion (i.e., bubble) in the mesa. A rerouted trench may have a uniform width over its length, or may have a width that varies or changes (e.g., widens or narrows) in different trench portions over its length.

FIG. 4 shows portions of an example device layout 500 of a shielded gate trench MOSFET device that includes bubble mesas with widened portions for making bridge connection trenches between adjoining trenches.

As shown in FIG. 4, device layout 500 may include multiple bubble mesas (e.g. mesas 502) and adjoining trenches (e.g., trenches 501) that generally run (e.g., aligned) parallel (e.g., substantially parallel) to each other longitudinally (in the y direction) across the device layout. The trenches may include gate and shield electrodes (not shown) of the device.

A mesa 502 may include one or more widened portions (e.g., a bubble portion 510) along its length (e.g., in the y direction). The mesa 502 may have a width in the x direction. The width of the mesa outside bubble portion 510 may, for example, generally be Wm. The width of the mesa in bubble portion 510 may, for example, be Wmb, where Wmb is greater than Wm.

Bridge connection trenches (e.g., bridge connection trench 505) linking or joining adjoining trenches may be disposed across the bubble portions of the mesa. Bubble connection trench 505 may have a same width (in the x-direction) as the width (i.e., Wmb) of the bubble portion of the mesa.

Disposing bubble connection trench 505 may involve cutting or etching mesa 502 in bubble portion 510 and opening a passageway connecting the two adjacent trenches 501. Mesa 502 may be divided or cut into two mesa segments (e.g., mesa segments 502A and 502B) by bubble connection trench 505 with each mesa segment (e.g., mesa segments 502A and 502B) having (i.e., terminating with) an end face portion 502f (e.g., in the x-z plane) at bubble connection trench 505. End face portion 502f of each mesa segment 502A and 502B terminating or ending at bubble connection trench 505 may have the larger width (i.e., Wmb) of the bubble portion of the mesa rather than the smaller width Wm of non-bubble portions of the mesa. Having the larger width for end face portion 502f can result in better charge balance and higher BVdss in the shielded gate trench MOSFET device.

The shield electrodes (shield poly) of the device may be extended into bubble connection trench 505 (as shown, e.g., in FIG. 1B or 2B) and exposed as a shield electrode contact element (e.g., bridge shield electrode contact element 504sc) in bubble connection trench 505.

In example implementations, a number of mesas in a device layout that are bubble mesas and have bridge connection trenches to adjoining trenches may be based on consideration of the characteristics (e.g., shield poly resistance) of the shielded gate trench MOSFET device.

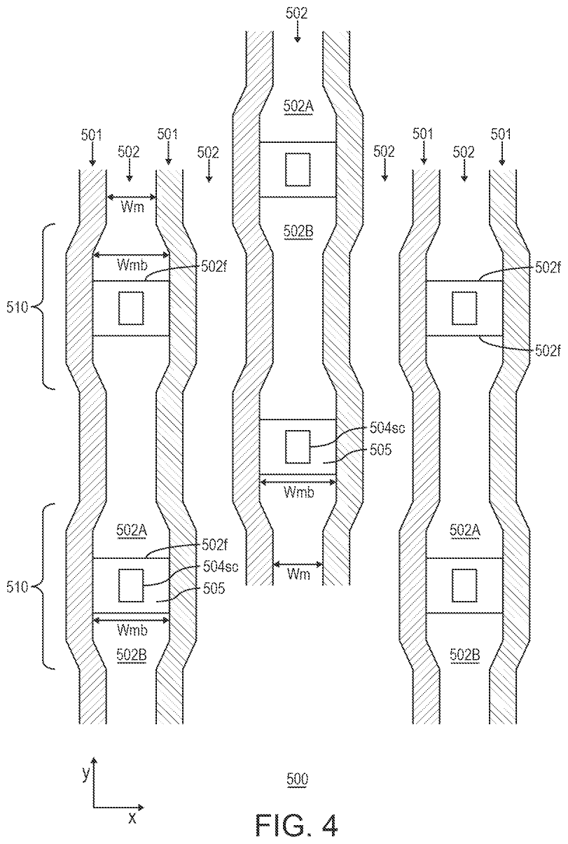

FIG. 5 shows, for example, a portion of a device layout 600 having a mesa pattern (e.g., mesa pattern 602P) including a number of bubble mesas and a number of non-bubble mesas. The mesa pattern may represent a device cell that is repeated across the device.

As shown in FIG. 5, mesa pattern 602P includes, for example, a number of bubble and non-bubble mesas (e.g., three bubble mesas 502(1), 502(3), and 502(5), and two non-bubble mesas 502(2) and 502(4)). The bubble mesas (i.e., mesas 502(1), 502(3), and 502(5)) are shown, for example, as alternating with the non-bubble mesas (i.e., mesas 502(2) and 502(4)) in the x direction. Bubble mesas 502(1) and 502(5) include bridge connection trenches 505 along an axis HH-HH (parallel to the x-axis). Bubble mesas 502(3) include a bridge connection trench 505 along an axis GG-GG (parallel to the x-axis) and another bridge connection trench 505 along an axis JJ-JJ (parallel to the x-axis). Axis GG-GG and axis JJ-JJ may each be a vertical distance AD (in the y direction) apart from axis HH-HH (in other words, bridge connection trenches 505 on mesas 502(1) and 502(5) are staggered in distance (in the y direction) compared to bridge connection trenches 505 on mesa 502(3). The non-bubble mesas (i.e., mesas 502(2) and 503(4)) may not have any bridge connection trenches 505 (at least in the portion of layout 600 shown in FIG. 5).

As previously noted, an actual MOSFET device may include arrays of hundreds or thousands of trenches/device cells, which may be obtained, for example, by repeating (e.g., in the x direction) mesa structures and patterns (e.g., mesa pattern 602P).

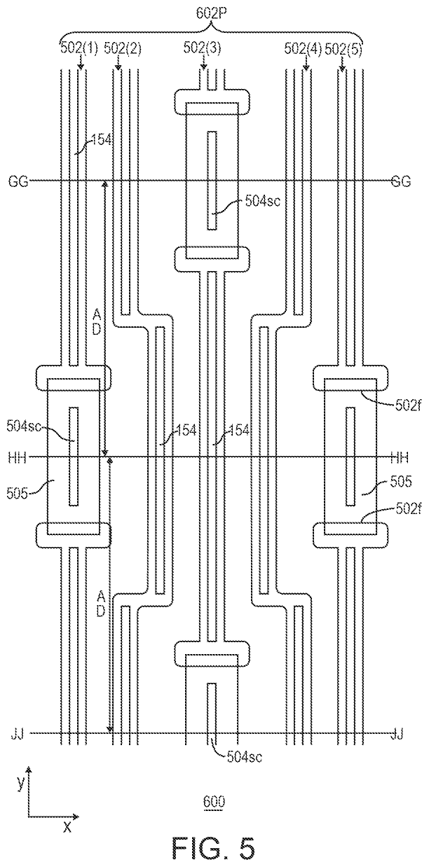

FIG. 6 illustrates use of an example repeatable pattern (e.g., mesa pattern 702P) of bubble mesas in a device layout (e.g., device layout 700). Mesa pattern 702P) may be repeatable (e.g., in the x direction) across device layout 700.

FIG. 6 shows only a portion of device layout 700 in the y-direction and the x-direction. Mesa pattern 702P may, for example, include a number of bubble mesas extending, for example, in the y direction. Mesa pattern 702P may, for example, include two bubble mesas 502(6) and 502(7) with bridge connection trenches 505 showing in the portion of device layout shown in FIG. 6, and several (e.g., about twelve) mesas 502nb that may have bridge connection trenches 505 outside (e.g., in the y direction) of the portion of device layout 700 shown in FIG. 6. In device layout 700, bubble mesas 502(6) in mesa patterns 702P may include bridge connection trenches 505 disposed to inter-connect or link adjoining trenches 501 along an axis KK-KK (parallel to the x-axis). Bubble mesas 502(7) in mesa patterns 702P may include bridge connection trenches 505 disposed to inter-connect or link adjoining trenches 501 along an axis LL-LL (parallel to the x-axis). Axis KK-KK and axis LL-LL may be a vertical distance BD (in the y direction) apart (in other words, bridge connection trenches 505 are staggered in distance (in the y direction) along the lengths of bubble mesas 502(6) and 502(7).

FIG. 7A shows, in cross-sectional view, an example shielded gate trench MOSFET device 100.

Shielded gate trench MOSFET device 100 may include a mesa 102 disposed between vertical trenches 101 formed in, for example, an epitaxial layer 130 on a semiconductor substrate 105. Mesa 102 may, for example, include doped semiconductor regions for forming a channel of the MOSFET device (e.g., source region 152, body region 153, a body region-to-source contact region 153c, source and body contact element 154, and drift region 155, etc.) of shielded gate trench MOSFET device 100. In example implementations, source region 152 may be heavily doped with an n-type dopant (e.g., arsenic or phosphorus) and body region 153 may be doped with p-type dopant (e.g., boron). A drain contact (e.g. drain contact 105d) may be disposed on a backside of substrate 105.

Trenches 101 may include a shield electrode 104s and a gate electrode 104g. Shield electrode 104s may be disposed below gate electrode 104g in trench 101. A gate oxide 104gox isolates gate electrode 104g and a shield oxide 104sox isolates shield electrode 104s in trench 101 from mesa 102.

FIG. 7B is a top view of a portion of an example contact structure layout (e.g., layout 800) of a shielded gate trench MOSFET device (e.g., shielded gate trench MOSFET device 100) in a planar stripe configuration. Shielded gate trench MOSFET device 100 may include parallel trenches 101 that extend, for example, in stripes in a y direction, between, for example, gate metal areas (e.g., gate metal runners 104gm) in layout 800.

Mesas 102 may be disposed between adjacent trenches 101. Mesas 102, which may include doped regions for forming a channel of the MOSFET device (e.g., source region 152, body region 153, source and body contact element 154, and drift region 155, etc., (FIG. 7A)), may expose source and body contact elements 154 in a x-y plane of layout 800. A source metal layer (e.g., source metal 154m) may contact the source and body contact elements 154 across trenches 101 in the x-y plane of layout 800.

Gate electrodes and shield electrodes (e.g., gate electrode 104g, shield electrode 104s, (FIG. 7A)) may be disposed in trenches 101. The shield electrodes (e.g., shield electrode 104s) may be disposed below or underneath gate electrodes 104g in trenches 101. The gate electrodes and shield electrodes are not visible in FIG. 7B because they are buried in trenches 101. However, gate electrode contact elements (e.g., gate electrode contact elements 104gc) for contacting the gate electrodes in trenches 101 may be exposed, for example, in a x-y plane of layout 800. FIG. 7B shows, for example, gate electrode contact elements 104gc disposed at ends of trenches 101 in a top portion and a bottom portion of layout 800. Gate electrode contact elements 104gc may be contacted by gate metal runners (e.g., gate metal runners 104gm). FIG. 7B shows, for example, a first gate metal runner 104gm contacting gate electrode contact elements 104gc at one end of trenches 101 and a second gate metal runner 104gm contacting the gate electrode contact elements 104gc at the other end of trenches 101.

Further, shield electrode contact elements 104sc may be exposed in the x-y plane of the device for contacting the shield electrodes in trenches 101. Shield electrode contact elements 104sc may be exposed by bringing shield poly to the surface vertically upward through trenches 101 (breaking or dividing the gate electrode disposed above the shield electrode in two discontinuous segments (not shown)). Shield electrode contact elements 104sc across the trenches 101 may be contacted by source metal 154m (e.g., in a shield contact area 104sca).

In the foregoing description, a trench (e.g., trench 201, FIG. 1A; trench 301, FIG. 2A; etc.) of a shielded gate trench MOSFET device generally has, for example, a uniform width Wt (in the x-direction). The trench with uniform width Wt can be referred to hereinafter as a narrow trench. Narrow trenches adjoining a mesa in the device layouts (e.g., device layouts, 200, 300, 400 and 500) may be inter-connected or linked by a bridge connection trench (e.g., bridge connection trenches 205, 305, 405, 505) disposed across the mesa (e.g., mesa 202, 302, 402 and 502). Shield electrodes in the narrow trenches adjoining the mesa may be exposed as bridge shield electrode contact elements (e.g., electrode contact elements 204sc, 304sc, 404sc, and 504sc) in the bridge connection trench.

In example implementations, the shielded gate trench MOSFET device may include other trenches (hereinafter wide trench) that have widths that can be non-uniform and may be larger than the uniform width Wt of a narrow trench. Shield electrode contact elements (e.g., shield electrode contact elements 104sc, FIG. 1B) may be exposed in the x-y plane of the device for contacting the shield electrodes in the wide trenches. A shield electrode contact element 104sc may be exposed by bringing the shield poly material of the shield electrode in the wide trench to the surface vertically upward through the wide trench (interrupting or segmenting any gate electrode that may be placed above the shield electrode in the trench).

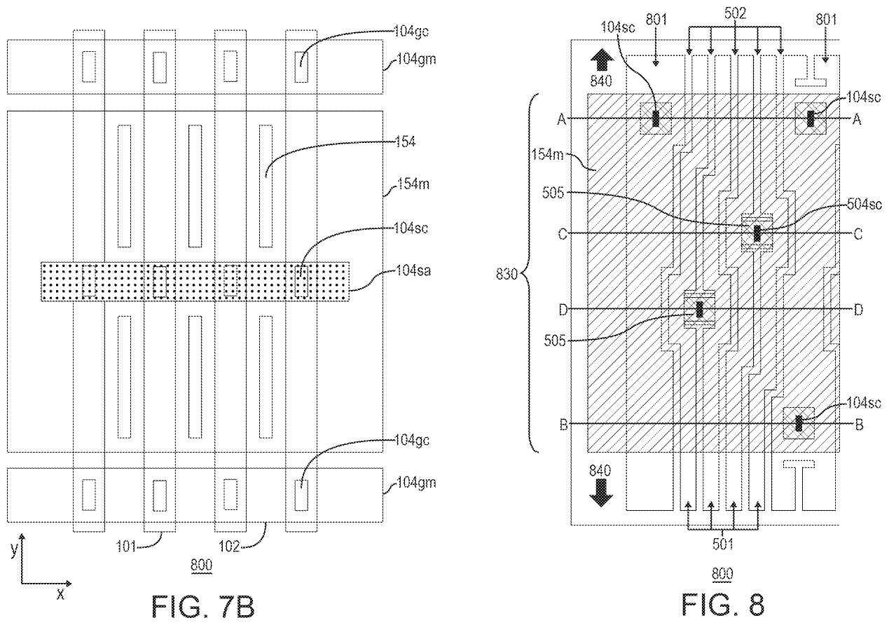

FIG. 8 shows an example device layout 800 of a shielded gate trench MOSFET device including both narrow trenches and wide trenches.

Device layout 800 includes, for example, narrow trenches (e.g., trenches 501) and wide trenches (e.g., trenches 801). Trenches 501 and trenches 801, and mesas (e.g., mesas 502) formed between adjoining trenches (e.g., trenches 501, or trenches 801) run longitudinally (e.g., in the y direction) across a shield contact area 830 between active regions 840 of the device.

Each of the trenches (e.g., trenches 501, and trenches 801) may include gate and shield electrodes (e.g., gate electrode 201G, shield electrode 201S, FIG. 1B) of the device.

The shield electrodes in trenches 801 may be exposed as shield electrode contact elements (e.g., shield electrode contact elements 104sc) in trenches 801 for contact by a source metal. The shield electrode contact elements 104sc may be formed in trenches 801 at locations about horizontal axes (e.g., axis A-A, and axis B-B) across shield contact area 830.

Further, the shield electrodes in trenches 501 may be exposed as shield electrode contact elements (e.g., bridge shield electrode contact elements 504sc) in bridge connection trenches (e.g., bridge connection trenches 505) linking adjoining trenches 501 across, for example, bubble mesas (e.g., mesas 502). The bridge connection trenches (e.g., bridge connection trenches 505) may be disposed in shield contact area 830, for example, about horizontal axes (e.g., axis C-C, and axis D-D). The bridge shield electrode contact elements 504sc may be formed in the bridge connection trenches (e.g., bridge connection trenches 505) about the horizontal axes (e.g., axis C-C, and axis D-D) in shield contact area 830.

As shown in FIG. 8, the shield electrode contact elements (e.g., shield electrode contact elements 104sc in trenches 801, and shield electrode contact elements 504sc in the bridge connection trenches 805) in device layout 800 may both be connected to an overlay of a source metal 154m.

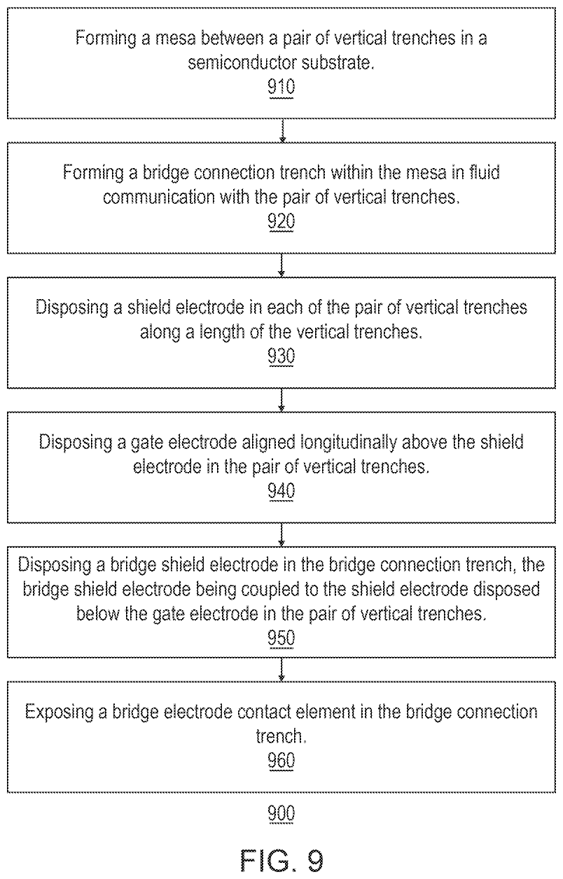

FIG. 9 shows an example method 900 for making contacts to shield electrodes in a shielded gate trench MOSFET device.

Method 900 includes forming a mesa between a pair of vertical trenches in a semiconductor substrate (910), forming a bridge connection trench within the mesa in fluid communication with the pair of vertical trenches (920), disposing a shield electrode in each of the pair of vertical trenches along a length of the vertical trenches (930), and disposing a gate electrode aligned longitudinally above the shield electrode in the pair of vertical trenches (940).

Method 900 further includes disposing a bridge shield electrode in the bridge connection trench, the bridge shield electrode being coupled to the shield electrode running longitudinally underneath the gate electrode in the pair of vertical trenches (950), and exposing a bridge shield electrode contact element in the bridge connection trench (960). In some implementations of method 900, the bridge shield electrode may be disposed in the bridge connection trench at 950 in a same processing step also disposing the shield electrode in each of the pair of vertical trenches at 930.

Method 900 may further include connecting the bridge shield electrode contact element to a source metal of the device.

Steps of method 900 may be performed sequentially or concurrently in any order of individual steps and any combination of the individual steps. For example, the bridge connection trench across the mesa (e.g., forming a bridge connection trench within the mesa at step 920) can be formed at the same time as the pair of vertical trenches defining the mesa (using a single mask and etch process) (e.g., forming a mesa between a pair of vertical trenches in a semiconductor substrate at step 910), or separately formed after the mesa is formed (using two different mask and etch processes). In other words steps 910 and 920 may be combined or may be separate sequential steps.

Specific structural and functional details disclosed herein are merely representative for purposes of describing example embodiments. Example embodiments, however, may be embodied in many alternate forms and should not be construed as limited to only the embodiments set forth herein.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), and/or so forth.

The terminology used herein is for the purpose of describing particular implementations only and is not intended to be limiting of the implementations. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Example implementations of the present inventive concepts are described herein with reference to cross-sectional illustrations that are schematic illustrations of idealized implementations (and intermediate structures) of example implementations. As such, variations from the shapes of the illustrations as a result, for example, of manufacturing techniques and/or tolerances, are to be expected. Thus, example implementations of the present inventive concepts should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of example implementations.

It will be understood that although the terms “first,” “second,” etc. may be used herein to describe various elements, these elements should not be limited by these terms. These terms are only used to distinguish one element from another. Thus, a “first” element could be termed a “second” element without departing from the teachings of the present implementations.

Unless otherwise defined, all terms (including technical and scientific terms) used herein have the same meaning as commonly understood by one of ordinary skill in the art to which this present inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A device, comprising:
a mesa disposed between a pair of vertical trenches in a semiconductor substrate, the pair of vertical trenches including a first vertical trench aligned parallel to a second vertical trench from the pair of vertical trenches;
a gate electrode disposed in each of the pair of vertical trenches;
a shield electrode disposed below each of the gate electrodes in the pair of vertical trenches;
a bridge connection trench traversing the mesa and joining the pair of vertical trenches, the bridge connection trench being aligned along a direction perpendicular to the parallel direction of the pair of vertical trenches; and
a bridge shield electrode disposed in the bridge connection trench and coupled to each of the shield electrodes in the pair of vertical trenches.

2. The device of claim 1, wherein the bridge shield electrode exposes a shield electrode contact element in the bridge connection trench.

3. The device of claim 2, wherein the shield electrode contact element in the bridge connection trench is connected to a source metal of the device.

4. The device of claim 1, wherein each of the pair of vertical trenches and the bridge connection trench have about a same vertical depth.

5. The device of claim 4, wherein the bridge shield electrode disposed in the bridge connection trench has about a same height as a height of the shield electrode disposed below each of the gate electrodes in the pair of vertical trenches.

6. The device of claim 5, wherein the bridge shield electrode is isolated from the gate electrode by a dielectric layer.

7. The device of claim 5, wherein the bridge shield electrode in the bridge connection trench is covered by a full fill oxide layer up to about a top surface of the mesa.

8. The device of claim 7, wherein a hole is disposed in the full fill oxide layer to expose a bridge shield electrode contact element in the bridge connection trench.

9. The device of claim 1, wherein the mesa has a horizontal width Wm over a portion of a length of the mesa, and wherein the mesa has a widened horizontal width Wmb in a portion of the mesa traversed by the bridge connection trench, where Wmb is greater than Wm.

10. The device of claim 1, wherein the bridge connection trench is a first bridge connection trench and traverses the mesa at a first location, and wherein the device further comprises:
a second bridge connection trench traversing the mesa at a second location and joining the pair vertical trenches, the bridge shield electrode being additionally disposed in the second bridge connection trench.

11. The device of claim 10, wherein the bridge shield electrode exposes a first shield electrode contact element in the first bridge connection trench and exposes a second shield electrode contact element in the second bridge connection trench.

12. The device of claim 11, wherein the first shield electrode contact element in the first bridge connection trench and the second shield electrode contact element in the second bridge connection trench are connected to a source metal of the device.

13. A device, comprising:
a first mesa disposed between a first pair of vertical trenches in a semiconductor substrate;
a second mesa disposed between a second pair of vertical trenches in the semiconductor substrate,
the first mesa, the second mesa, and the first and second pairs of vertical trenches extending longitudinally from an active region of the device through a shield contact area of the device on the semiconductor substrate;
a gate electrode disposed in each of the first and second pairs of vertical trenches;
a shield electrode disposed underneath the gate electrode in each of the first and second pairs of vertical trenches;
a first bridge connection trench disposed across the first mesa at a first location, the first bridge connection trench in fluid communication with the first pair of vertical trenches; and
a second bridge connection trench disposed across the second mesa at a second location, the second bridge connection trench in fluid communication with the second pair of vertical trenches.

14. The device of claim 13, wherein the first location on the first mesa and the second location on the second mesa are separated longitudinally along the mesas' lengths by a distance.

15. The device of claim 13, wherein a bridge shield electrode is disposed in the first bridge connection trench across the first mesa at the first location, the bridge shield electrode being coupled to the shield electrode disposed underneath the gate electrode in each of the first pairs of vertical trenches.

16. The device of claim 15, wherein the first bridge connection exposes a first shield electrode contact element in the first bridge connection trench.

17. The device of claim 16, wherein the first shield electrode contact element in the first bridge connection is connected to a source metal of the device.

18. The device of claim 13, wherein the bridge shield electrode rises along a side of the gate electrode to a height in the first bridge connection trench greater than a height of the shield electrode disposed underneath the gate electrode in each of the first and second pairs of vertical trenches.

19. The device of claim 13, wherein the bridge shield electrode has about a same height in the first bridge connection trench as a height of the shield electrode disposed underneath the gate electrode in each of the first pair of vertical trenches.

20. The device of claim 13, further comprising:
a gate electrode disposed in a vertical trench; and
a shield electrode disposed underneath the gate electrode in the vertical trench, the shield electrode rising vertically, at a third location, to a surface of the device from underneath the gate electrode to expose a third shield electrode contact element.

21. A method, comprising:
forming a mesa between a pair of vertical trenches in a semiconductor substrate;
forming a bridge connection trench within the mesa in fluid communication with the pair of vertical trenches;
disposing a shield electrode in each of the pair of vertical trenches along a length of the pair of vertical trenches;
disposing a gate electrode aligned longitudinally above the shield electrode in the pair of vertical trenches; and
disposing a bridge shield electrode in the bridge connection trench, the bridge shield electrode being coupled to the shield electrode disposed below the gate electrode in the pair of vertical trenches.

22. The method of claim 21, further comprising:
exposing a shield electrode contact element in the bridge connection.

23. A device, comprising:
a mesa disposed between a pair of vertical trenches in a semiconductor substrate;
a gate electrode disposed in each of the pair of vertical trenches;
a shield electrode disposed below each of the gate electrodes in the pair of vertical trenches;
a bridge connection trench traversing the mesa, the bridge connection trench in fluid communication with each of the pair of vertical trenches; and
a bridge shield electrode disposed in the bridge connection trench, the bridge shield electrode coupled to the shield electrode disposed below each of the gate electrodes in the pair of vertical trenches.
